(19) United States
(12) Patent Application Publication
(10) Pub. No.: US 2021/0343878 A1
(43) Pub. Date: Nov. 4, 2021

(54) THIN-FILM TRANSISTOR AND METHOD FOR MANUFACTURING SAME

(71) Applicant: SAKAI DISPLAY PRODUCTS CORPORATION, Sakai-shi, Osaka (JP)

(72) Inventor: HIROYUKI OHTA, Sakai-shi, Osaka (JP)

(21) Appl. No.: 17/283,442

(22) PCT Filed: Oct. 11, 2018
(86) PCT No.: PCT/JP2018/037944

§ 371 Date: Apr. 7, 2021

(51) Int. Cl. H01L 29/786; H01L 27/12; H01L 29/66

(52) U.S. Cl. CPC H01L 29/78696; H01L 27/1229; H01L 29/78693; H01L 29/78669; H01L 21/02686; H01L 29/66969; H01L 29/66765; H01L 27/1274; H01L 27/1225; H01L 29/78678

(57) ABSTRACT

A thin film transistor 101 includes: a gate electrode 2; a gate insulating layer 3; a semiconductor layer 4 including an amorphous semiconductor layer 4a and a crystalline semiconductor layer 4c that is disposed on a portion of the amorphous semiconductor layer 4a, the semiconductor layer 4 including an active region Rc that includes the crystalline semiconductor layer 4c and a portion of the amorphous semiconductor layer 4a, and the semiconductor layer 4 including first and second semiconductor regions Rs and Rd which respectively include first and second amorphous portions A1 and A2 that are located on opposite sides of the active region Rc; a protective insulating layer 5; first and second contact layers Cs and Cd disposed on the semiconductor layer 4 and the protective insulating layer 5; a source electrode 8s; and a drain electrode 8d. The first contact layer Cs includes a first amorphous contact layer 7s that is directly in contact with the first semiconductor region Rs and a portion of a side surface of the crystalline semiconductor layer 4c. The second contact layer Cd includes a second amorphous contact layer 7d that is directly in contact with the second semiconductor region Rd and another portion of the side surface of the crystalline semiconductor layer 4c.

### TECHNICAL FIELD

The present invention relates to a thin film transistor and a method of producing the same.

### BACKGROUND ART

Thin film transistors (hereinafter, “TFT”) are used as switching elements on an active matrix substrate of a display apparatus such as a liquid crystal display apparatus or an organic EL display apparatus, for example. In the present specification, such TFTs will be referred to as “pixel TFTs”. As pixel TFTs, amorphous silicon TFTs whose active layer is an amorphous silicon film (hereinafter abbreviated as an “a-Si film”), and polycrystalline silicon TFTs whose active layer is a polycrystalline silicon (polysilicon) film (hereinafter abbreviated as a “poly-Si film”) have been widely used. Generally speaking, a poly-Si film has a higher field-effect mobility than that of an a-Si film, and therefore a polycrystalline silicon TFT has a higher current driving power (i.e., a larger ON current) than that of an amorphous silicon TFT. As the material of the active layer of a TFT, semiconductors other than silicon, e.g., oxide semiconductors such as In—Ga—Zn—O-based semiconductors, may also be used.

A TFT having a gate electrode disposed at the substrate side of the active layer is referred to as a “bottom-gate type TFT”, whereas a TFT having a gate electrode disposed above its active layer (i.e., the opposite side from the substrate) is referred to as a “top-gate type TFT”. In some cases, forming bottom-gate type TFTs as the pixel TFTs may have cost advantages relative to forming top-gate type TFTs. Polycrystalline silicon TFTs are usually of top-gate type, but polycrystalline silicon TFTs of bottom-gate type have also been proposed.

Known types of bottom-gate type TFTs are channel-etch type TFTs (hereinafter “CE-type TFT”) and etch-stop type TFTs (hereinafter “ES-type TFT”). In a CE-type TFT, an electrically conductive film is formed directly upon an active layer, and this electrically conductive film is patterned to provide a source electrode and a drain electrode (source-drain separation). On the other hand, in an ES-type TFT, a source-drain separation step is performed while a channel section of the active layer is covered with an insulating layer that functions as an etchstop (hereinafter referred to as a “protective insulating layer”).

For example, Patent Documents 1 and 2 disclose bottom-gate type (ES type) TFTs whose active layer is a polycrystalline (or amorphous) silicon layer. In these documents, a semiconductor layer containing an impurity is provided between the active layer and each of the source and drain electrodes of the TFT. In the present specification, a low-resistance semiconductor layer that connects an electrode and the active layer is referred to as a “contact layer”.

### CITATION LIST

### Patent Literature

[Patent Document 1] Japanese Laid-Open Patent Publication No. 6-151856

[Patent Document 2] International Publication No. 2016/157351

### SUMMARY OF INVENTION

### Technical Problem

The pixel TFTs of an active matrix substrate are required to improve in terms of not only ON characteristics, but also OFF characteristics.

However, in conventional ES-type TFTs, in a region where the gate electrode and the drain electrode overlap, a leak current may occur from a high electric field between the gate and the drain owing to a quantum mechanical tunneling effect (gate-induced drain leakage (GIDL)), thus resulting in a large OFF-leak current. The details will be described later. When there is a large OFF-leak current, displaying characteristics may deteriorate, e.g., display unevennesses occurring when the display panel is activated.

Embodiments of the present invention have been made in view of the above circumstances, and an objective thereof is to provide a thin film transistor which allows for reduction of an OFF-leak current, and a method of producing the same.

### Solution to Problem

A thin film transistor according to an embodiment of the present invention is a thin film transistor comprising: a substrate; a gate electrode supported by the substrate; a gate insulating layer covering the gate electrode; a semiconductor layer being disposed on the gate insulating layer and including an amorphous semiconductor layer and a crystalline semiconductor layer that is disposed on a portion of the amorphous semiconductor layer, the semiconductor layer including an active region, a first semiconductor region and a second semiconductor region, the active region including the crystalline semiconductor layer and the portion of the amorphous semiconductor layer, the first semiconductor region and the second semiconductor region, when viewed from a normal direction of the substrate, respectively including a first amorphous portion and a second amorphous portion of the amorphous semiconductor layer that are located on opposite sides of the active region; a protective insulating layer disposed on the crystalline semiconductor layer so as to expose a side surface of the crystalline semiconductor layer and the first semiconductor region and the second semiconductor region; a first contact layer disposed on the semiconductor layer and the protective insulating layer, the first contact layer including a first amorphous contact layer composed of an amorphous semiconductor, the first amorphous contact layer being directly in contact with the first semiconductor region of the semiconductor layer and with a portion of the side surface of the crystalline semiconductor layer; a second contact layer disposed on the semiconductor layer and the protective insulating layer, the second contact layer including a second amorphous contact layer composed of an amorphous semiconductor, the second amorphous contact layer being directly in contact with the second semiconductor region of the semiconductor layer and with another portion of the side surface of the crystalline semiconductor layer; a source electrode electrically connected to the crystalline semiconductor layer via the first contact layer; and a drain electrode electrically connected to the crystalline semiconductor layer via the second contact layer.

In one embodiment, the first amorphous contact layer is directly in contact with the first amorphous portion of the amorphous semiconductor layer, and the second amorphous contact layer is directly in contact with the second amorphous portion of the amorphous semiconductor layer.

In one embodiment, when viewed from the normal direction of the substrate, peripheral edges of the protective insulating layer and the crystalline semiconductor layer are aligned with each other.

In one embodiment, the first amorphous contact layer and the second amorphous contact layer are n type amorphous semiconductor layers containing an n type impurity.

In one embodiment, the first amorphous contact layer and the second amorphous contact layer are i type amorphous semiconductor layers that substantially do not contain any n type impurity.

In one embodiment, the crystalline semiconductor layer and the amorphous semiconductor layer are composed of a same semiconductor film.

In one embodiment, the semiconductor layer includes, between the crystalline semiconductor layer and the amorphous semiconductor layer, a transitional region containing crystal particles dispersed within an amorphous semiconductor.

In one embodiment, the crystalline semiconductor layer and the amorphous semiconductor layer are composed of mutually different semiconductor films.

In one embodiment, the crystalline semiconductor layer is a polysilicon layer, and the amorphous semiconductor layer is an amorphous silicon layer.

In one embodiment, the crystalline semiconductor layer is a crystalline oxide semiconductor layer, and the amorphous semiconductor layer is an amorphous oxide semiconductor layer.

A display apparatus according to an embodiment of the present invention comprises: the thin film transistor of any of the above; and a displaying region including a plurality of pixels, wherein the thin film transistor is disposed correspondingly to each of the plurality of pixels.

A method of producing a thin film transistor according to an embodiment of the present invention is a production method for a thin film transistor supported by a substrate, comprising: (A) a step of forming, on the substrate, a gate electrode and a gate insulating layer covering the gate electrode; (B) a step of forming an amorphous semiconductor film on the gate insulating layer; (C) a step of irradiating at least a portion of a surficial portion of the amorphous semiconductor film with laser light to melt and solidify the portion and form a crystalline region, and to leave a portion that is located below the surficial portion as an amorphous region, the step thus forming a semiconductor film that includes the amorphous region and the crystalline region; (D) a step of forming a protective insulating film on the semiconductor film; (E) a step of, by using a first mask, patterning the protective insulating film and the semiconductor film to form from the protective insulating film a protective insulating layer that covers only a portion of the crystalline region and to thin-film any portion of the semiconductor film that is not covered by the protective insulating layer, the step thus forming a semiconductor layer that includes an amorphous semiconductor layer formed from the amorphous region and a crystalline semiconductor layer formed from the portion of the crystalline region, the semiconductor layer including, when viewed from a normal direction of the substrate, an active region that includes the crystalline semiconductor layer and includes a portion of the amorphous semiconductor layer that is located under the crystalline semiconductor layer, and a first semiconductor region and a second semiconductor region which respectively include portions of the amorphous semiconductor layer that are located on opposite sides of the active region; (F) a step of forming a film for contact layer formation that covers the protective insulating layer and the semiconductor layer, the film for contact layer formation being a film of amorphous semiconductor, or a multilayer film having a film of an amorphous semiconductor as a lowermost layer; (G) a step of forming an electrically conductive film on the film for contact layer formation; and (H) a step of, by using the protective insulating layer as an etchstop, patterning the film for contact layer formation and the electrically conductive film to form from the electrically conductive film a source electrode and a drain electrode that are separated from each other, and to form from the film for contact layer formation a first contact layer and a second contact layer, wherein the first contact layer is located between the semiconductor layer and the source electrode and is directly in contact with a portion of a side surface of the crystalline semiconductor layer and with the first semiconductor region, and wherein the second contact layer is located between the semiconductor layer and the drain electrode and is directly in contact with another portion of the side surface of the crystalline semiconductor layer and with the second semiconductor region.

In one embodiment, in step (E), the portion of the semiconductor film that is not covered by the protective insulating layer is thin-filmed until the amorphous region is exposed.

In one embodiment, the amorphous semiconductor layer is an amorphous silicon layer, and the crystalline semiconductor layer is a polysilicon layer.

In one embodiment, the crystalline semiconductor layer is a crystalline oxide semiconductor layer, and the amorphous semiconductor layer is an amorphous oxide semiconductor layer.

In one embodiment, the film of amorphous semiconductor of the film for contact layer formation is an n type amorphous silicon film containing an n type impurity.

### Advantageous Effects of Invention

According to an embodiment of the present invention, there is provided a thin film transistor which allows for reduction of an OFF-leak current, and a method of producing the same.

### BRIEF DESCRIPTION OF DRAWINGS

FIG. 1 (a) and (b) are a schematic plan view and a cross-sectional view, respectively, of a TFT 101 according to the first embodiment.

FIG. 2 (a) is a cross-sectional view for describing the structure of a semiconductor layer 4 that is formed by laser annealing technique; and (b) is a schematic enlarged cross-sectional view illustrating an example crystal structure of the semiconductor layer 4.

FIG. 3 (a) to (q) are schematic step-by-step cross-sectional views for describing an example method of producing the TFT 101.

FIG. 4 (a) and (b) are a schematic plan view and a cross-sectional view, respectively, of a TFT 102 according to Variant 1; and (c) is a schematic enlarged cross-sectional view of a contact layer of the TFT 102.

FIG. 5 A cross-sectional view of a TFT 103 according to Variant 2.

FIG. 6 (a) to (d) are each a schematic step-by-step cross-sectional views describing an example method of producing the TFT 103.

FIG. 7 A diagram showing an energy band structure near a junction interface between an i type a-Si layer and a poly-Si layer.

FIG. 8 A schematic enlarged cross-sectional view of an interface between a poly-Si layer and an i type a-Si layer.

FIG. 9 (a) and (b) are schematic cross-sectional views of a heterojunction-containing TFT 801 and a homojunction-containing TFT 802, respectively, that were used for measurement.

FIG. 10 A diagram showing C-V characteristics of the heterojunction-containing TFT 801 and the homojunction-containing TFT 802.

FIG. 11 A diagram showing an energy band structure near a junction interface between a poly-Si layer and an n⁺ type Si layer.

### DESCRIPTION OF EMBODIMENTS

The inventors have found that, in a conventional polycrystalline silicon TFT whose active layer is a polysilicon (poly-Si) layer, forming a contact layer having an intrinsic amorphous silicon (an i type a-Si layer) as a lowermost layer on the poly-Si layer allows a heterojunction to be formed by the poly-Si layer and the i type a-Si layer, whereby a two-dimensional electron gas (hereinafter “2DEG”) may be generated as in the case of a high-electron mobility transistor (HEMT). When a 2DEG is generated at an interface between a poly-Si layer and a contact layer (i.e., when electrons accumulate at this interface), the GIDL may further increase.

2DEG refers to, when a junction is formed between two kinds of semiconductors of different band gap energies, a layer of electrons (i.e., a two-dimensional distribution of electrons) that is created at that interface (in a region which is about 10 nm thick near the interface). 2DEG is known to be composed of a compound semiconductor that may be GaAs-based, InP-based, GaN-based, SiGe-based, etc. However, it has not been known that 2DEG can ever occur at a junction interface between a poly-Si layer and any other semiconductor layer (e.g., an intrinsic amorphous silicon layer (hereinafter “i type a-Si layer”)) having a band gap energy larger than that of poly-Si.

In the present specification, a junction between two semiconductor layers of different band gap energies (e.g., a junction between an i type a-Si layer and a poly-Si layer) is referred to a “semiconductor heterojunction”, and a junction between two semiconductor layers of similar band gap energies (e.g., a junction between an i type a-Si layer and an n⁺ type a-Si layer) is referred to as a “semiconductor homojunction”.

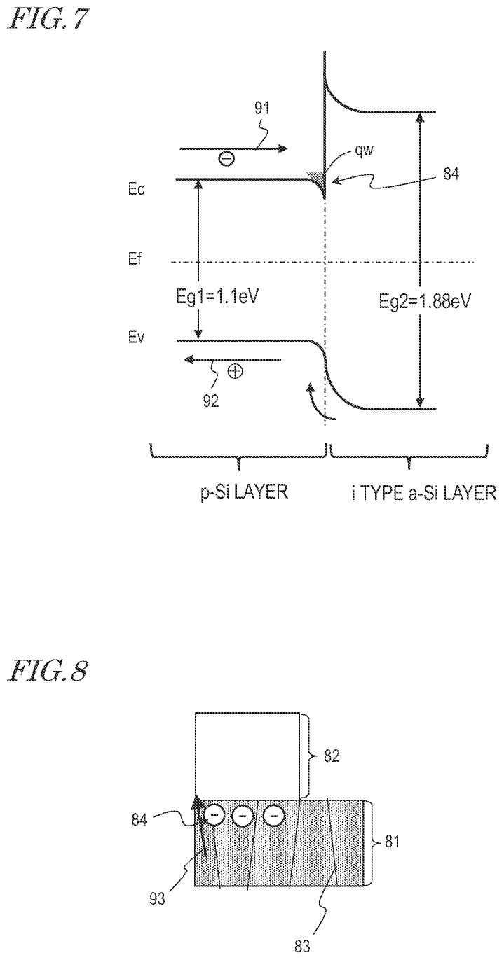

FIG. 7 is a schematic diagram for describing an example of an energy band structure near the interface of a semiconductor heterojunction. This illustrates a semiconductor heterojunction that is created, in a polycrystalline silicon TFT of bottom-gate type, by disposing an i type a-Si layer on a non-doped poly-Si layer (active layer).

The poly-Si layer has a band gap energy Eg1 of about 1.1 eV, whereas the i type a-Si layer has a band gap energy Eg2 of about 1.88 eV. A depletion layer is formed at the poly-Si layer side. In FIG. 7, a flow of electrons is indicated by arrow 91, whereas a flow of holes is indicated by arrow 92. It is considered that, as shown in the figure, a quantum well qw is created at an interface between the i type a-Si layer and the poly-Si layer, in which electrons accumulate to generate 2DEG. Hereinafter, the region 84 in which 2DEG is generated will be referred to as a “2DEG region”.

FIG. 8 is a schematic enlarged cross-sectional view of the interface between a poly-Si layer 81 and an i type a-Si layer 82. When the poly-Si layer 81 is used as an active layer of a TFT and the i type a-Si layer 82 is used as the lowermost layer of a contact layer, a 2DEG region 84 may emerge at the interface between them. Once the 2DEG region 84 emerges, electrons in the 2DEG region 84 are more likely to move along the grain boundaries in the poly-Si layer 81 (arrow 93) toward the i type a-Si layer 82, thus causing an increased leak current.

Next, a capacitance measurement which was conducted by the inventors in order to confirm an occurrence of 2DEG at the interface of a semiconductor heterojunction will be described.

FIGS. 9(a) and (b) are schematic cross-sectional views of ES-type TFTs 801 and 802, respectively, that were used in the capacitance measurement. The TFT 801 is a TFT having a semiconductor heterojunction between the gate and the source/drain (referred to as a “heterojunction-containing TFT”), whereas the TFT 802 is a TFT having a semiconductor homojunction between the gate and the source/drain (referred to as a “homojunction-containing TFT”).

The heterojunction-containing TFT 801 includes: a gate electrode 2 formed on a substrate; a gate insulating layer 3 covering the gate electrode 2; a semiconductor layer (active layer) 4 formed on the gate insulating layer 3; a protective insulating layer (etch stop layer) 5 covering a channel region of the semiconductor layer 4; and a source electrode 8a and a drain electrode 8d. The semiconductor layer 4 is a polysilicon layer (poly-Si layer). Between the semiconductor layer 4 and protective insulating layer 5 and the source electrode 8o, and between the semiconductor layer 4 and protective insulating layer 5 and the drain electrode 8d, an i type a-Si layer 6A composed of an intrinsic amorphous silicon and an n⁺ type a-Si layer 6B composed of n⁺ type amorphous silicon are disposed in this order as contact layers. The i type a-Si layer 6A and the semiconductor layer 4 are directly in contact. The junction site g1 between the semiconductor layer 4, which is a poly-Si layer, and the i type a-Si layer 6A has a semiconductor heterojunction.

On the other hand, the homojunction-containing TFT 802 is similar in configuration to the heterojunction-containing TFT 801, except that an amorphous silicon layer (a-Si layer) is used as the semiconductor layer 4 and that a contact layer composed only of an n type a-Si layer 6B is used. The junction site g2 between the semiconductor layer 4, which is an a-Si layer, and the n⁺ type a-Si layer 6B is a semiconductor homojunction.

By using a TFT monitor and applying an AC current (10 kHz) between the gate and the source, measurements of a capacitance C between the gate and the source were taken for the heterojunction-containing TFT 801 and the homojunction-containing TFT 802.

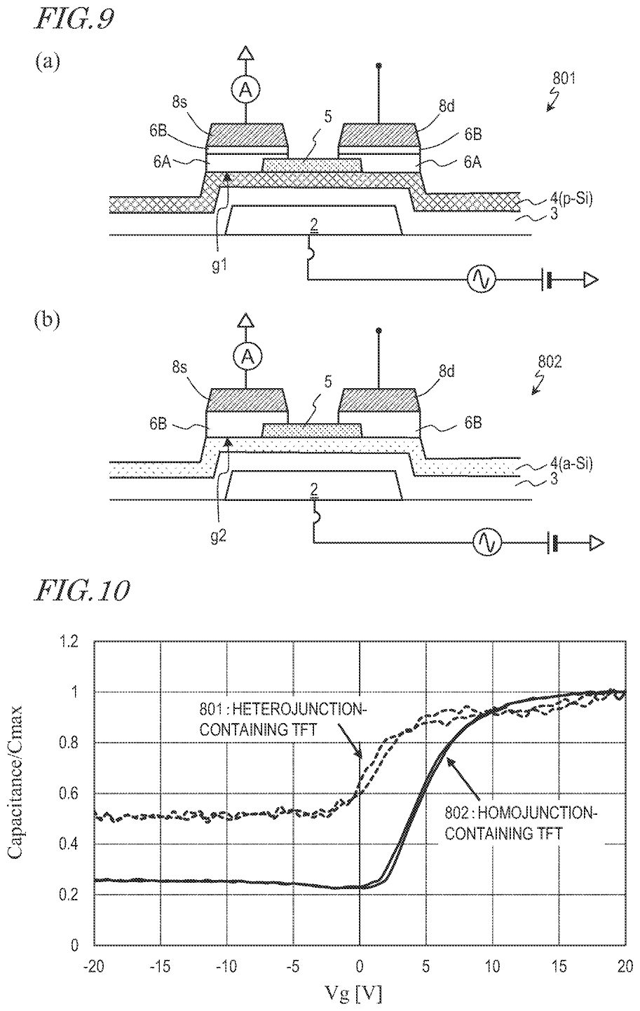

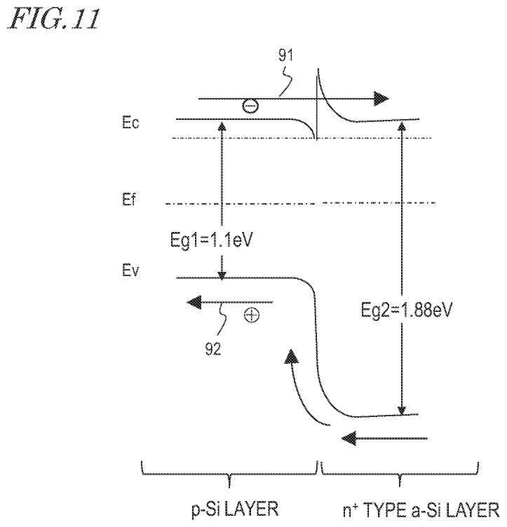

FIG. 10 is a diagram showing C-V characteristics of the heterojunction-containing TFT 801 and the homojunction-containing TFT 802, where the vertical axis represents capacitance C and the horizontal axis represents gate voltage Vg.

From FIG. 10, it can be seen that there is a smaller change in the capacitance of the heterojunction-containing TFT 801 than there is for the homojunction-containing TFT 802. This is indicative of a difference in carrier concentration (electrons). It is generally known that, as the carrier concentration increases, a semiconductor more closely resembles a metal, thus resulting in a smaller change in capacitance. In the heterojunction-containing TFT 801, electrons are considered to accumulate in the quantum well qw, which is formed at the interface of the junction site g1 to cause 2DEG, thus making the carrier concentration correspondingly greater (i.e., because of the electrons distribution in the 2DEG) than that of the homojunction-containing TFT 802. One can confirm from this that 2DEG has been generated at the interface of the semiconductor heterojunction. Note that when a positive voltage is applied as the gate voltage Vg, the electrons having accumulated in the quantum well qw at the interface of the junction site g1 are presumably discharged toward the semiconductor layer 4 in the heterojunction-containing TFT 801, thus resulting in a carrier concentration which is similar to that of the homojunction-containing TFT 802.

The inventors have sought for a TFT structure that can suppress 2DEG generation at an interface between an active layer and a contact layer, which may cause a leak current, thereby arriving at the present invention.

Hereinafter, with reference to the drawings, embodiments of the present invention will be described specifically.

### First Embodiment

A thin film transistor (TFT) according to a first embodiment is a polycrystalline silicon TFT of etchstop (ES) type. The TFT of the present embodiment is applicable to circuit boards for active matrix substrates or the like, various display apparatuses such as liquid crystal display apparatuses and organic EL display apparatuses, image sensors, electronic appliances, and so on.

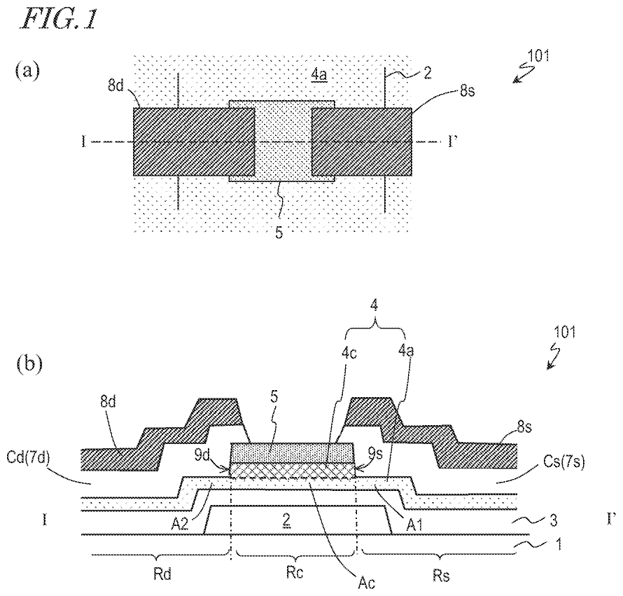

FIG. 1(a) is a schematic plan view of a thin film transistor (TFT) 101 according to the present embodiment, and FIG. 1(b) is a cross-sectional view of the TFT 101 taken along line I-I′.

The TFT 101 is supported on a substrate 1 such as a glass substrate, and includes: a gate electrode 2; a gate insulating layer 3 covering the gate electrode 2; a semiconductor layer (active layer) 4 disposed on the gate insulating layer 3; a protective insulating layer (also referred to as an etch stop layer) 5 disposed on a portion of the semiconductor layer; and a source electrode 8a and a drain electrode 8d.

The semiconductor layer 4 is a layer functioning as an active layer of the TFT 101, and includes an amorphous semiconductor layer and a crystalline semiconductor layer disposed on a portion of the amorphous semiconductor layer. The crystalline semiconductor layer includes a region in which a channel of the TFT 101 is formed (channel region). Herein, an example will be described where the amorphous semiconductor layer is an amorphous silicon layer (a-Si layer) 4a mainly containing amorphous silicon and the crystalline semiconductor layer is a polysilicon layer (poly-Si layer) 4c mainly containing crystalline silicon.

The semiconductor layer 4 includes: the a-Si layer 4a; and a poly-Si layer 4c disposed on a portion of the a-Si layer 4a. A lower face of the a-Si layer 4a may be directly in contact with the gate insulating layer 3. The poly-Si layer 4c is disposed so as to overlap the gate electrode 2 via the gate insulating layer 3, and includes a region to become the channel of the TFT 101 (channel region).

The semiconductor layer 4 includes: an active region Rc including the poly-Si layer 4c and a portion Ac of the a-Si layer 4a that is located under the poly-Si layer 4c; and, a first semiconductor region Rs and a second semiconductor region Rd that are respectively located on opposite sides of the active region Rc when viewed from the normal direction of the substrate 1. The first semiconductor region Ra includes a first amorphous portion A1 of the a-Si layer 4a that is located at the source side of the active region Rc, whereas the second semiconductor region Rd includes a second amorphous portion A2 of the a-Si layer 4a that is located at the drain side of the active region Rc. The first semiconductor region Ra and the second semiconductor region Rd do not include the poly-Si layer 4c, and therefore are thinner than the active region Rc.

The a-Si layer 4a and the poly-Si layer 4c may be continuous (i.e., composed of one film). In this case, between the a-Si layer 4a and the poly-Si layer 4c, a transitional region may be present which contains crystal particles dispersed in amorphous silicon. Such a semiconductor layer 4 can be obtained by, for example, etching a silicon semiconductor film that is crystallized only in the surficial portion, and thin-filming the portions to become the first semiconductor region Rs and the second semiconductor region Rd (i.e., removing their surficial portions). The detailed process will be described later.

The protective insulating layer 5 covers at least the active region Rc of the semiconductor layer 4, and yet does not cover the first semiconductor region Rs and the second semiconductor region Rd. In this example, the protective insulating layer 5 is disposed on the poly-Si layer 4c so as to expose a side surface of the poly-Si layer 4c, the first semiconductor region Rs, and the second semiconductor region Rd. The protective insulating layer 5 may be directly in contact with an upper face (e.g., the entire upper face in this example) of the poly-Si layer 4c. The protective insulating layer 5 functions as an etchstop in a step of forming the source electrode 8s and the drain electrode 8d (source-drain separation step), thus protecting the channel region.

When viewed from the normal direction of the substrate 1, peripheral edges of the protective insulating layer 5 and the poly-Si layer 4c may be aligned with each other. Such structure is obtained by patterning the protective insulating layer 5 and the poly-Si layer 4c by using the same mask. The protective insulating layer 5 and the poly-Si layer 4c may be island-shaped.

The source electrode B and the drain electrode 8d are provided above the semiconductor layer 4 and the protective insulating layer 5, so as to be spaced apart from each other. Between the semiconductor layer 4 and the source electrode 8a, a first contact layer Cs that electrically connects the source electrode 8s and the semiconductor layer 4 (poly-Si layer 4c) is provided; between the semiconductor layer 4 and the drain electrode 8d, a second contact layer Cd that electrically connects the drain electrode 8d and the semiconductor layer 4 (poly-Si layer 4c) is provided. An end of the first contact layer Cs that is closer to the channel region and an end of the second contact layer Cd that is closer to the channel region may be located on an upper face of the protective insulating layer 5, so as to be spaced apart from each other. In this case, a portion of the protective insulating layer 5 is located between the poly-Si layer 4c and the first contact layer Cs, while another portion is located between the poly-Si layer 4c and the second contact layer Cd.

The first contact layer Ca includes a first amorphous contact layer 7s that is composed of an amorphous semiconductor, whereas the second contact layer Cd includes a second amorphous contact layer 7d that is composed of an amorphous semiconductor. The first amorphous contact layer 7s and the second amorphous contact layer 7d (which may hereinafter collectively referred to as the “amorphous contact layer 7”) may be e.g., an n type amorphous silicon (n type a-Si) layer that contains an n type impurity, or may be a non-doped amorphous silicon (i type a-Si) layer that substantially does not contain any n type impurity (e.g., having an n type impurity concentration that is equal to or smaller than the measurement limit by SIMS (e.g., 1×10⁷ atoms/cm³ or less by the apparatus used herein)).

The first contact layer Cs and the second contact layer Cd (which may hereinafter be collectively referred to as the “contact layer C”) may have a multilayer structure whose lowermost layer is the amorphous contact layer 7, or be a single amorphous contact layer 7. In other words, the lower face of the contact layer C is the lower face of the amorphous contact layer 7.

The amorphous contact layer 7 is disposed so as to be in contact with the first semiconductor region Rs or the second semiconductor region Rd of the semiconductor layer 4, and in contact with the side surface of the poly-Si layer 4c. Herein, a lower face of the first amorphous contact layer 7s (i.e., a lower face of the first contact layer Cs) is directly in contact with an upper face of the first semiconductor region Rs of the semiconductor layer 4 (which herein is an upper face of the first amorphous portion A1 of the a-Si layer 4a), and with a portion of the side surface of the poly-Si layer 4c (i.e., a portion of the side surface of the poly-Si layer 4c that is located at the source side; hereinafter referred to as the “first side surface subportion”) 9s. The first amorphous contact layer 7s may further be in contact with a side surface and an upper face of the protective insulating layer 5, too. Similarly, a lower face of the second amorphous contact layer 7d (i.e., a lower face of the second contact layer Cd) is directly in contact with an upper face of the second semiconductor region Rd of the semiconductor layer 4 (which herein is an upper face of the second amorphous portion A2 of the a-Si layer 4a), and with a portion of the side surface of the poly-Si layer 4c (i.e., a portion of the side surface of the poly-Si layer 4c that is located at the drain side; hereinafter referred to as the “second side surface subportion”) 9d. The second amorphous contact layer 7d may further be in contact with a side surface and an upper face of the protective insulating layer 5, too.

On the other hand, an upper face of the first contact layer Cs may be directly in contact with the source electrode 8s, and an upper face of the second contact layer Cd may be directly in contact with the drain electrode 8d.

Although not shown in the figure, the contact layer C may have a multilayer structure of amorphous semiconductor layers (e.g., a-Si layers) of different n type impurity concentrations. For example, an uppermost layer of the contact layer C (i.e., a layer that is in contact with the source electrode 8s or the drain electrode 8d) may be an n⁺ type amorphous silicon layer that contains an n type impurity at a concentration higher than that in any other layer. Moreover, the amorphous contact layer 7 may be a concentration-gradient layer whose n type impurity concentration has a gradient in the thickness direction. In the case where the contact layer C has a multilayer structure, it suffices if the contact layer C has an amorphous contact layer 7 of amorphous semiconductor as its lowermost layer, and the contact layer C may further include a layer(s) other than the amorphous semiconductor (a microcrystalline silicon layer(s), a polysilicon layer(s), etc.).

(Formation Method and the Crystal Structure of the Semiconductor Layer 4)

The semiconductor layer 4 according to the present embodiment, which includes an amorphous semiconductor layer and a crystalline semiconductor layer, may be composed of the same semiconductor film, for example. In this case, the amorphous semiconductor layer and the crystalline semiconductor layer contain the same semiconductor material, although having different crystal structures. For example, when the semiconductor layer 4 is made by using an oxide semiconductor film such as an In—Ga—Zn—O-based semiconductor film, the composition (i.e., the ratio between metallic elements, e.g., In:Ga:Zn in the case of an In—Ga—Zn—O-based semiconductor) of the oxide semiconductor contained in the amorphous semiconductor layer (amorphous oxide semiconductor layer) and that in the crystalline semiconductor layer (crystalline oxide semiconductor layer) of the semiconductor layer 4 are essentially identical.

Hereinafter, the formation method and the crystal structure of the semiconductor layer 4 will be described, by taking as an example the case where a single amorphous silicon film is used, from which the a-Si layer 4a is formed as an amorphous semiconductor layer and the poly-Si layer 4c is formed as a crystalline semiconductor layer.

The semiconductor layer 4 is formed by using laser annealing technique for example. In a laser annealing technique, usually, an a-Si film on a substrate is irradiated with laser light. The region of the a-Si film that has been heated and melted through laser light absorption becomes crystallized when being cooled and solidified via thermal diffusion into the substrate. Within the a-Si film, the largest depth of a portion that can be melted instantaneously through laser light irradiation is referred to as the “melting depth”. In the case of laser annealing using a KrF excimer laser, the “melting depth” of a-Si is e.g. about 50 nm, although depending on the annealing conditions (see Hyoumen Kagaku, or Surface Science Vol. 24, No. 6, pp. 375-382, 2003). Therefore, it is difficult to crystallize the entirety of a thick a-Si film, e.g. thicker than 50 nm, by laser annealing technique; conventionally, an a-Si film having a thickness equal to or less than the melting depth is formed, and the entire a-Si film is crystallized through laser irradiation, thereby forming a crystalline silicon film (polysilicon film).

On the other hand, according to the present embodiment, a characteristic aspect of the laser annealing technique is utilized, i.e., that a portion of the semiconductor film that is located below a predetermined depth (melting depth) is not crystallized; accordingly, laser irradiation is performed for an a-Si film that is sufficiently thicker than the melting depth. As a result of this, only a surficial portion (upper portion) of the a-Si film is crystallized, thereby forming a poly-Si region in a portion of the surficial portion to become at least the channel region. The portion which is located closer to the substrate 1 than the poly-Si region and which is therefore not crystallized remains as an a-Si region. Then, this semiconductor film is patterned so that portions of the semiconductor film (i.e., portions located on opposite sides of the channel region) are thin-filmed, whereby the semiconductor layer 4 including the a-Si layer 4a and the poly-Si layer 4c is formed. For the patterning of the semiconductor film, the same mask that is used for patterning the protective insulating layer 5 may be used. A more specific formation method and conditions for the semiconductor layer 4 will be described later.

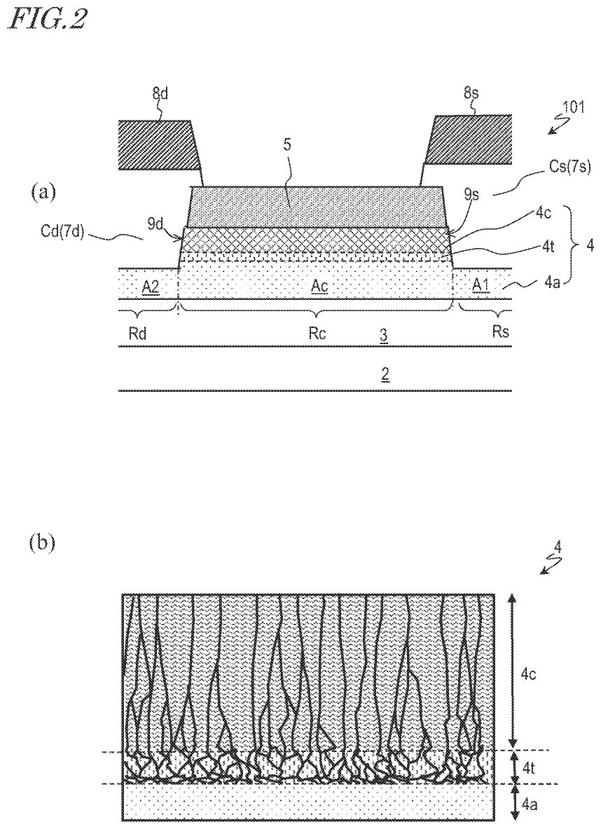

FIG. 2(a) is a cross-sectional view for describing the structure of a semiconductor layer 4 that is formed by laser annealing technique. FIG. 2(b) is a schematic enlarged cross-sectional view illustrating an exemplary crystal structure of the semiconductor layer 4.

The semiconductor layer 4 includes an a-Si layer 4a and a poly-Si layer 4c located over the a-Si layer 4a. In the poly-Si layer 4c, crystal grains have grown in columnar shapes toward the upper face of the semiconductor layer 4. Although not particularly limited, the size of the crystal grains may be e.g. about not less than 30 nm and not more than 150 nm.

The thickness of the poly-Si layer 4c is e.g. 30 nm or more. When the thickness of the poly-Si layer 4c (i.e., the channel region) is 30 nm or more, some contact area can be provided between the side surface subportions 9s and 9d of the poly-Si layer 4c and the contact layer C, whereby ON resistance can be reduced. The thickness of the poly-Si layer 4c may be controlled based on the conditions of laser annealing, for example. However, there is a limit to the melting depth, as described above; therefore, the thickness of the poly-Si layer 4c is 70 nm or less, for example.

The thickness of the a-Si layer 4a in the first semiconductor region Ra and the second semiconductor region Rd may be e.g. not less than 10 nm and not more than 50 nm. When it is not less than 10 nm, loss of the a-Si layer 4a due to in-plane variations in the etching amount can be better prevented. When it is not more than 50 nm, the main current path in ON periods is the poly-Si layer 4c, whereby a decrease in the ON current can be suppressed.

A transitional region 4t may be included between the poly-Si layer 4c and the a-Si layer 4a. The transitional region 4t is an intermixed phase of a crystal phase and an amorphous phase, and contains crystal particles dispersed within an amorphous semiconductor (e.g., microcrystal particles), for example. The size of the crystal particles in the transitional region is smaller than the crystal particles in the poly-Si layer 4c, and may be e.g. a grain size on the order of not less than 2 nm and not more than 10 nm. The thickness of the transitional region 4t may vary depending on the laser annealing conditions and the like; although not particularly limited, it may be e.g. not less than 10 nm and not more than 30 nm. Formation of the transitional region 4t between the a-Si layer 4a and the poly-Si layer 4c reduces interfacial strain associated with crystallization, and reduces the interface state between the a-Si layer 4a and the poly-Si layer 4c. Therefore, GIDL can be reduced more effectively.

Although preferably the transitional region 4t is removed in the first semiconductor region Ra and the second semiconductor region Rd, some of it may remain, without being completely removed.

(Effect)

According to the present embodiment, at the interface between the semiconductor layer 4 and the contact layer C, the GIDL associated with a two-dimensional electron gas (2DEG) can be suppressed. Hereinafter, the reason thereof will be described.

As has been described above with reference to FIG. 7 and FIG. 8, at the interface of a heterojunction, electrons may accumulate in the quantum well qw to generate 2DEG. As in the heterojunction-containing TFT 801 (FIG. 9(a)), when the interface between the semiconductor layer 4 and the contact layer has a heterojunction (e.g., a junction between a poly-Si layer and an i type a-Si layer in the case of the heterojunction-containing TFT 801), 2DEG may be generated, whereby the leak current (GIDL) may increase.

The problem of a leak current associated with 2DEG may occur when the Fermi levels of the poly-Si layer and the a-Si layer to become the lowermost layer in the contact layer prior to junction are of a relationship that allows the aforementioned quantum well qw to be formed as a result of the junction (FIG. 7). In particular, at an interface of the junction site g1 between a poly-Si layer that does not contain any conductivity-imparting impurity (i.e., non-doped) and an a-Si layer that substantially does not contain an impurity (i.e., intrinsic), an increase in the leak current owing to the 2DEG region will be significant.

On the other hand, in the TFT 101 according to the present embodiment, no heterojunction is formed at an interface of the junction site g between the first semiconductor region Ra and the second semiconductor region Rd of the semiconductor layer 4 and the contact layer C. For example, the junction site g has a homojunction between amorphous semiconductors (e.g., between a-Si and a-Si herein). Therefore, the aforementioned 2DEG region is not formed. Therefore, GIDL associated with 2DEG can be suppressed, so that an OFF-leak current can be reduced more effectively.

Note that the interface between the side surface subportions 9s and 9d of the poly-Si layer 4c and the contact layer C has a heterojunction, but the junction interface is parallel to the direction of a strong field, and thus the area in which electrons accumulate is reduced. Therefore, it is presumable that the influences exerted on the leak current (GIDL) by the electrons accumulating at the junction interface are small.

Preferably the first semiconductor region Ra and the second semiconductor region Rd of the semiconductor layer 4 do not include the transitional region 4t. Consequently, at the junction site g, the a-Si layer 4a and the amorphous contact layer 7 are directly in contact, whereby 2DEG generation can be more effectively suppressed.

Note that the transitional region 4t may be partially or wholly exposed at the surface of the first semiconductor region Rs and the second semiconductor region Rd of the semiconductor layer 4. The transitional region 4t is a region in which microcrystalline silicon and a-Si are mixed, and its band gap value is a value close to that of a-Si; therefore, the discrepancy in band between the transitional region 4t and the amorphous contact layer 7 (i.e., a difference in band gap energy) is smaller than the discrepancy between the poly-Si and the amorphous contact layer 7. Therefore, 2DEG is unlikely to be generated at the junction interface between the transitional region 4t and the amorphous contact layer 7. As a result, even when the amorphous contact layer 7 and the transitional region 4t are in contact at the junction site g, an increase in the leak current owing to 2DEG can be suppressed.

The amorphous contact layer 7 may be an amorphous semiconductor layer containing an n type impurity (e.g., an n type a-Si layer). As a result, the ON resistance between the contact layer C and the side surface subportions 9s and 9d of the poly-Si layer 4c can be reduced, whereby high ON characteristics can be realized. Moreover, as is illustrated in FIG. 11, 2DEG is unlikely to be generated at the interface between the side surface subportions 9s and 9d of the poly-Si layer 4c and the n⁺ type a-Si layer (or, if at all it is generated, the electron density in the 2DEG region will be small), thus making it even less likely for a leak current to occur. In the amorphous contact layer 7, the n type impurity concentration along the thickness direction may be constant, or have a gradient.

The n type impurity concentration of the lower face of the amorphous contact layer 7 (i.e., a portion that is in contact with the first semiconductor region Ra and the second semiconductor region Rd) may be e.g. not less than 1.2×10¹⁷ atoms/cm³ and not more than 1×10²³ atoms/cm³. Preferably, it may be not less than 5×10¹ atoms/cm³ and not more than 1×10²³ atoms/cm³.

Alternatively, the amorphous contact layer 7 may be an i type a-Si layer that substantially does not contain any n type impurity (e.g., having an n type impurity concentration that is equal to or smaller than the measurement limit by SIMS (e.g., 1×10¹⁷ atoms/cm- or less by the apparatus used herein)). Since 2DEG is likely to occur at the interface between an i type a-Si layer and the poly-Si layer 4c, applying the multilayer structure of the semiconductor layer according to the present embodiment to an amorphous contact layer 7 incorporating such TFTs will provide more a more outstanding effect.

On the other hand, the n type impurity concentration in the portions of the contact layer C that are in contact with the drain electrode 8d and the drain electrode 8d (e.g., the uppermost layer in the contact layer C) may be set to a concentration that is suitable as that of a contact region with electrodes, e.g. not less than 5×10¹⁹ atoms/cm³ and not more than 1×10²³ atoms/cm³.

<Method of Producing the TFT 101>

Next, an example of a method of producing the TFT 101 will be described.

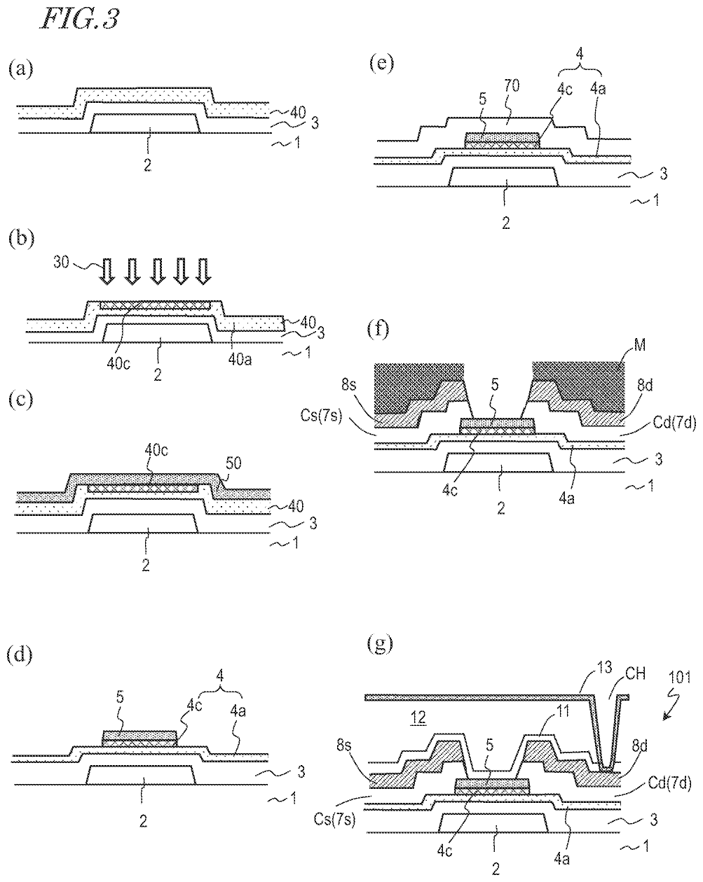

FIG. 3(a) to FIG. 3(g) are schematic step-by-step cross-sectional views for describing an example of a method of producing the TFT 101.

First, as shown in FIG. 3(a), on a substrate 1, a gate electrode 2, a gate insulating layer 3, and an amorphous semiconductor film 40 for the active layer are formed in this order.

As the substrate 1, a substrate having a dielectric surface, e.g., a glass substrate, a silicon substrate, or a plastic substrate (resin substrate) having heat resistance, can be used.

The gate electrode 2 is formed by forming an electrically conductive film for the gate on the substrate 1, and patterning it. Herein, for example, an electrically conductive film for the gate (thickness: e.g. about 500 nm) is formed on the substrate 1 by sputtering, and the metal film is patterned by using a known photolithography process. For the etching of the electrically conductive film for the gate, wet etching may be used, for example.

The material of the gate electrode 2 may be: an elemental metal such as molybdenum (Mo), tungsten (W), copper (Cu), chromium (Cr), tantalum (Ta), aluminum (Al), or titanium (Ti); a material composed of these with nitrogen, oxygen, or other metals contained therein; or a transparent electrically conductive material such as indium tin oxide (ITO).

The gate insulating layer 3 is formed on the substrate 1 having the gate electrode 2 formed thereon, by a plasma CVD technique, for example. As the gate insulating layer (thickness: e.g. about 0.4 μm) 3, for example, a silicon oxide (SiO₂) layer, a silicon nitride (SiNx) layer, or a multilayer film of an SiO₂ layer(s) and an SiNx layer(s) may be formed.

The amorphous semiconductor film 40 for the active layer may be formed by a CVD technique by using a hydrogen gas (H₂) and a silane gas (SiH₄), for example. The amorphous semiconductor film 40 for the active layer may be a non-doped amorphous silicon film that substantially does not contain any n type impurity. A non-doped amorphous silicon film is an a-Si film which is formed without intentional addition of an n type impurity (e.g. by using a material gas that does not contain any n type impurity). Note that the amorphous semiconductor film 40 for the active layer may contain an n type impurity at a relatively low concentration. The thickness of the amorphous semiconductor film 40 is set so as to be larger than the melting depth in the laser annealing to be subsequently performed. The thickness of the amorphous semiconductor film 40 may be e.g. not less than 60 nm, preferably not less than 70 nm. On the other hand, the thickness of the amorphous semiconductor film 40 may be not more than 120 nm.

Next, as shown in FIG. 3(b), within the amorphous semiconductor film 40 for the active layer, a region including a portion to become the channel region of the TFT is irradiated with laser light 30. As the laser light 30, ultraviolet laser such as XeCl excimer laser (wavelength 308 nm), or solid laser of a wavelength or 550 nm or less, such as a second harmonic (wavelength 532 nm) of YAG laser, may be used. Through irradiation of laser light 30, the region of the amorphous semiconductor film 40 for the active layer that is irradiated with the laser light 30 melts and solidifies, whereby a poly-Si region 40c is formed. In this example, the poly-Si region 40c is formed only in a portion of the semiconductor film 40 that is at a depth equal to or less than the melting depth from the surface (i.e., a surficial portion). At the substrate 1 side of the poly-Si region 40c, Si does not undergo crystallization, and is left as an a-Si region 40a. A transitional region (see FIG. 2) may be formed between the a-Si region 40a and the poly-Si region 40c.

There is no particular limitation as to the crystallization method using laser light 30. For example, laser light 30 from a laser light source may be passed through a microlens array so that the laser light 30 is converged onto only a portion of the amorphous semiconductor film 40 for the active layer, thereby partly crystallizing the amorphous semiconductor film 40 for the active layer. In the present specification, this crystallization method is referred to as “local laser annealing”. By using local laser annealing, as compared to the conventional laser annealing where the entire surface a-Si film is scanned with linear laser light, the time required for crystallization can be greatly reduced, whereby mass producibility can be promoted.

The microlens array includes a two-dimensional or linear arrangement of microlenses. When a plurality of TFTs are formed on the substrate 1, the laser light 30 is converged by the microlens array so as to be incident, within the amorphous semiconductor film 40 for the active layer, only on a plurality of predetermined regions (irradiation regions) which are spaced apart from one another. Each irradiation region is disposed correspondingly to the portion of a TFT to become the channel region. The positions, number, shapes, sizes, etc., of irradiation regions can be controlled by the size and the array pitch of the microlens array (which is not limited to lenses under 1 mm), the opening positions in a mask that is disposed on the light source side of the microlens array, and the like. As a result, each region of the amorphous semiconductor film 40 for the active layer that has been irradiated with the laser light 30 is heated to melt and solidify, thus becoming the poly-Si region 40c. Any region that has not been irradiated with the laser light remains as the a-Si region 4a. Therefore, when local laser annealing is used, the a-Si region 40a is located at the substrate 1 side of the poly-Si region 40c and on the outside of the poly-Si region 40c as viewed from the normal direction of the substrate 1.

As to the more specific method of local laser annealing, the configuration (including the microlens array, mask structure) of the apparatus used for local laser annealing, the entire disclosure of International Publication No. 2011/055618, International Publication No. 2011/132559, International Publication No. 2016/157351, and International Publication No. 2016/170571 is incorporated herein by reference.

Next, as shown in FIG. 3(c), a protective insulating film 50 to become a protective insulating layer (etch stop layer) is formed on the semiconductor layer 40. Herein, as the protective insulating film 50, a silicon oxide film (SiO₂ film) is formed by the CVD technique. The thickness of the protective insulating film 50 may be not less than 30 nm and not more than 300 nm, for example. Thereafter, although not shown, the semiconductor layer 40 may be subjected to a dehydrogenation annealing treatment (e.g. 450° C., 60 minutes).

Next, as shown in FIG. 3(d), by using a resist mask (not shown), the protective insulating film 50 and the semiconductor film 40 are etched. Herein, dry etching is employed.

Through this patterning, an island-shaped protective insulating layer 5 that covers a portion of the semiconductor film 40 to become the channel region is obtained from the protective insulating film 50, and, in any region of the semiconductor film 40 that is not covered by the protective insulating layer 5, a surficial portion of the semiconductor film 40 is removed to expose the a-Si region 40a or a transitional region located below it. Preferably, this is performed under such conditions that, in any region that is not covered by the protective insulating layer 5, the poly-Si region 40c and the transitional region are removed and that the a-Si region 40a located below it is exposed. A surface portion of the a-Si region 40a may also be etched (overetching). As a result, an a-Si layer 4a that is in contact with the gate insulating layer 3 is obtained from the a-Si region 40a, and a poly-Si layer 4c that is identical in shape to the protective insulating layer 5 is obtained from the poly-Si region 40c. The poly-Si layer 4c is located between the protective insulating layer 5 and the a-Si layer 4a. Thus, a semiconductor layer 4 including the a-Si layer 4a and the poly-Si layer 4c is formed.

Next, as shown in FIG. 3(e), a film for contact layer formation is formed on the semiconductor layer 4. The film for contact layer formation may be a film of amorphous semiconductor, or a multilayer film whose lowermost layer is a film of amorphous semiconductor. Herein, as a film of amorphous semiconductor, by plasma CVD technique, an n⁺ type a-Si film (thickness: e.g. about 0.05 μm) 70 containing an n type impurity (which herein is phosphorus) is deposited. The n type impurity concentration is e.g. not less than 1.2×10¹⁷ atoms/cm³ and not more than 1×10²³ atoms/cm³. As the material gas, a gaseous mixture of silane, hydrogen, and phosphine (PH₃) is used.

The film for contact layer formation may have a multilayer structure. For example, by plasma CVD technique, a multilayer film may be formed that includes: an i type a-Si film (thickness: e.g. about 0.1 μm); and an n⁺ type a-Si film (thickness: e.g. about 0.05 μm containing an n type impurity (e.g., phosphorus)). As the material gases for the i type a-Si film, a hydrogen gas and a silane gas are used. As the material gas for the n⁺ type a-Si film, a gaseous mixture of silane, hydrogen, and phosphine (PH₃) is used.

Next, on the Si film for the contact layers (which herein is an n⁺ type a-Si film 70), an electrically conductive film for the source and the drain electrode (thickness: e.g. about 0.3 μm) and a resist mask M are formed. The electrically conductive film for the source and the drain electrode is formed with a material similar to that for the electrically conductive film for the gate, by a method similar to that used for the electrically conductive film for the gate.

Thereafter, by using the resist mask M, the electrically conductive film for the source and the drain electrode and the n⁺ type a-Si film 70 are patterned by dry etching, for example. As a result, as shown in FIG. 3(f), a source electrode 8s and a drain electrode 8d are formed from the electrically conductive film (source-drain separation step). Moreover, from the n⁺ type a-Si film 70, a first contact layer Cs and a second contact layer Cd are formed so as to be spaced apart from each other. During the patterning, the protective insulating layer 5 functions as an etchstop, so that the portion of the semiconductor layer 4 that is covered by the protective insulating layer 5 is not etched. The ends of the first contact layer Ca and the second contact layer Cd that are closer to the channel may be located on an upper face of the protective insulating layer 5. Thereafter, the resist mask M is removed off the substrate 1. Thus, the TFT 101 is produced.

In order to deactivate dangling bonds in the poly-Si layer 40c and reduce the defect density, the poly-Si layer 40c may be subjected to a hydrogen plasma treatment after the source-drain separation step.

In the case where the TFT 101 is used as a pixel TFT of an active matrix substrate, as shown in FIG. 3(g), an interlayer insulating layer is formed so as to cover the TFT 101. Herein, as the interlayer insulating layer, an inorganic insulating layer (passivation film) 11 and an organic insulating layer 12 are formed.

As the inorganic insulating layer 11, a silicon oxide layer, a silicon nitride layer, or the like may be used. Herein, as the inorganic insulating layer 11, an SiNx layer (thickness: e.g. about 200 nm) is formed by the CVD technique, for example. The inorganic insulating layer 11 is in contact with the protective insulating layer 5 in (a gap) between the source electrode 8 and the drain electrode 8d.

The organic insulating layer 12 may be an organic insulating film (thickness: e.g. 1 to 3 μm) containing a photosensitive resin material, for example. Thereafter, the organic insulating layer 12 is patterned, and an aperture is formed therein. Next, by using the organic insulating layer 12 as a mask, the inorganic insulating layer 11 is etched (dry etching). As a result, a contact hole CH that reaches the drain electrode 8d is formed in the inorganic insulating layer 11 and the organic insulating layer 12.

Next, a transparent electrically conductive film is formed on the organic insulating layer 12 and in the contact hole CH. As the material for the transparent electrode film, a metal oxide such as indium-tin oxide (ITO), indium-zinc oxide, or ZnO can be used. Herein, by e.g. sputtering, an indium-zinc oxide film (thickness: e.g. about 100 nm) is formed as the transparent electrically conductive film.

Thereafter, the transparent electrically conductive film is patterned by e.g. wet etching, thereby providing a pixel electrode 13. The pixel electrode 13 is to be disposed so as to be each spaced apart, from pixel to pixel. Each pixel electrode 13 is in contact with the drain electrode 8d of the corresponding TFT within the contact hole. Although not illustrated, the source electrode 8a of the TFT 101 is electrically connected to a source bus line (not shown), while the gate electrode 2 is electrically connected to a gate bus line (not shown).

The semiconductor layer 4, the first contact layer Cs, and the second contact layer Cd may be patterned into island shapes in the region where the TFT 101 is formed (TFT formation region). Alternatively, the semiconductor layer 4, the first contact layer Cs, and the second contact layer Cd may extend to regions other than the region where the TFT 101 is formed (TFT formation region). For example, the semiconductor layer 4 may extend so as to overlap a source bus line that is connected to the source electrode 8a. It suffices if the portion of the semiconductor layer 4 that is located in the TFT formation region contains the poly-Si layer 4c; the portion extending to regions other than the TFT formation region may be composed only of the a-Si layer 4a.

Moreover, the crystallization method of the amorphous semiconductor film 40 for the active layer is not limited to the aforementioned local laser annealing. A part or a whole of the amorphous semiconductor film 40 for the active layer may be crystallized by using other known methods.

The foregoing describes an example where the amorphous semiconductor layer to become the lower layer of the semiconductor layer 4 is the a-Si layer 4a and the crystalline semiconductor layer to become the upper layer thereof is the poly-Si layer 4c; however, the types, crystal structures, etc., of the amorphous semiconductor layer and the crystalline semiconductor layer are not limited in particular. For example, any semiconductor other than silicon, e.g., oxide semiconductor, may be used for the semiconductor layer 4. In this case, the lower layer of the semiconductor layer 4 may be an amorphous oxide semiconductor layer, and the upper layer thereof may be a crystalline oxide semiconductor layer. The crystalline oxide semiconductor may be a polycrystalline oxide semiconductor, a microcrystalline oxide semiconductor, a crystalline oxide semiconductor whose c axis is oriented essentially perpendicular to the layer plane, for example. The oxide semiconductor may be an In—Ga—Zn—O-based semiconductor, or any other known semiconductor. The material, structure, method of film formation, etc., of an amorphous or crystalline oxide semiconductor are described in the specification of Japanese Patent No. 6275294, for example. The entire disclosure of the specification of Japanese Patent No. 6275294 is incorporated herein by reference.

(Variant 1)

FIG. 4(a) is a plan view showing another TFT 102 according to the present embodiment. FIG. 4(b) is a cross-sectional view taken along line IV-IV′ in FIG. 4(a).

The TFT 102 according to Variant 1 differs from the TFT 101 shown in FIG. 1 in that the protective insulating layer 5 does not have an island-shaped pattern.

In this example, the protective insulating layer 5 has apertures 5s and 5d at the source side and the drain side of a portion of the semiconductor layer 4 to become a channel region. The apertures 5s and 5d are formed so as to expose a side surface of a poly-Si layer 4c and an upper face of an a-Si layer 4a (or the transitional region 4t), respectively. A portion of the semiconductor layer 4 that overlaps the aperture 5s becomes a first semiconductor region Rs; a portion thereof that overlaps the aperture 5d becomes an second semiconductor region Rd; and a portion thereof that is interposed therebetween becomes an active region Rc. The active region Rc includes: a portion Ac of the a-Si layer 4a that is interposed between the apertures 5s and 5d; and a portion of the poly-Si layer 4c that is interposed between the apertures 5s and 5d.

Within the aperture 5s, the first contact layer Cs is directly in contact with a first side surface subportion 9s of the poly-Si layer 4c and an upper face (which herein is an upper face of the first amorphous portion A1 of the a-Si layer 4a) of the first semiconductor region Rs. Within the aperture 5d, the second contact layer Cd is directly in contact with a second side surface subportion 9d of the poly-Si layer 4c and an upper face (which herein is an upper face of the second amorphous portion A2 of the a-Si layer 4a) of the second semiconductor region Rd.

The TFT 102 can also be formed by a similar method to the method described above with reference to FIG. 3. Since the semiconductor layer 4 is patterned (thin-filmed) by using the same mask as that for the protective insulating layer 5, the thickness of the portion of the semiconductor layer 4 that is covered by the protective insulating layer 5 (i.e., a portion not overlapping the apertures 5s and 5d) is greater than the thickness of the portions overlapping the apertures 5s and 5d.

Moreover, by using the aforementioned local laser annealing, only a predetermined region (i.e., the portion to become the channel region and its vicinity) of the semiconductor film 40 may be allowed to crystallize. In this case, regions R0 of the semiconductor layer 4 that are located on the outside of the first semiconductor region Rs and the second semiconductor region Rd (i.e., opposite to the channel) may not include any poly-Si region. For example, the regions R0 may include an a-Si layer having essentially the same thickness as that of the active region Rc of the semiconductor layer 4.

(Variant 2)

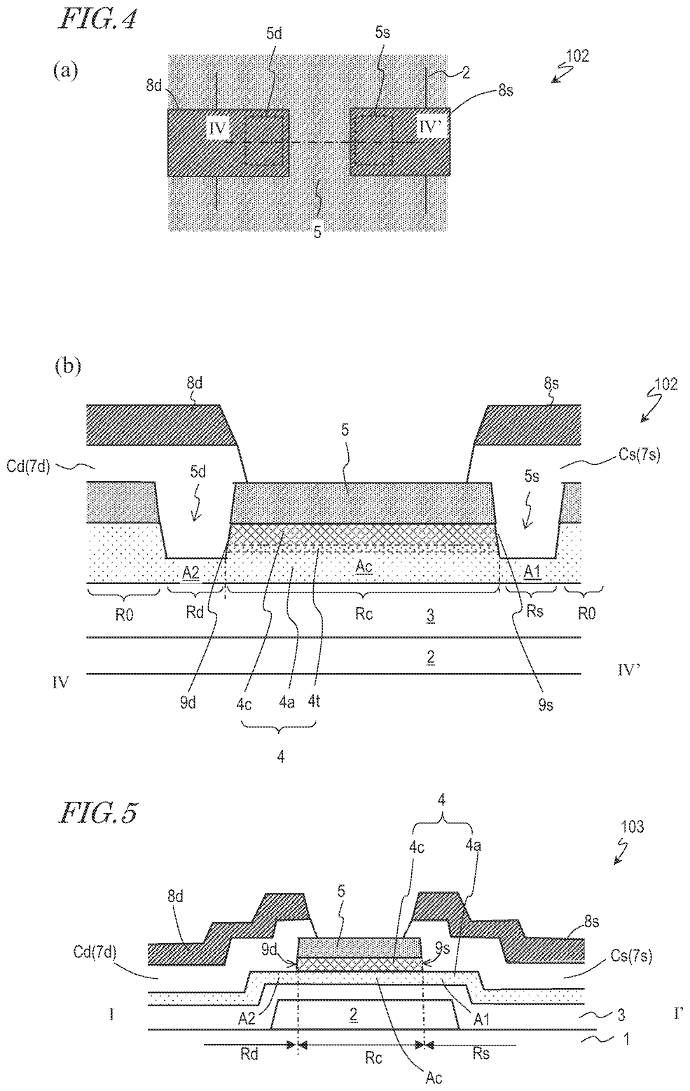

FIG. 5 is a cross-sectional view showing another TFT 103 according to the present embodiment.

In the TFT 101 shown in FIG. 1, the poly-Si layer 4c and the a-Si layer 4a in the semiconductor layer 4 are formed by crystallizing only portions of one semiconductor film (a-Si film). On the other hand, in Variant 2, the a-Si layer and the poly-Si layer are formed from mutually different semiconductor films (i.e., separately formed semiconductor films). Therefore, no transitional region is formed between the poly-Si layer and the a-Si layer.

The semiconductor layer 4 of the TFT 103 may be formed as follows.

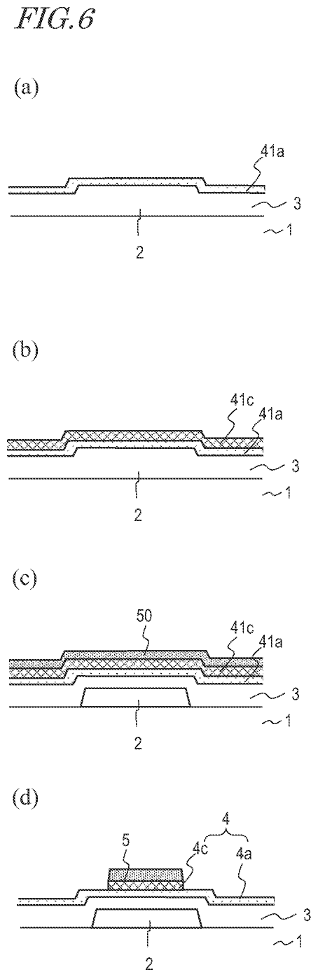

First, as shown in FIG. 6(a), an a-Si film 41a is formed on a gate insulating layer 3 by CVD technique, for example. Next, as shown in FIG. 6(b), a poly-Si film 41c is formed by CVD technique (high-density plasma CVD technique), for example. Thereafter, as shown in FIG. 6(c), a protective insulating film 50 is formed on the poly-Si film 41c. Next, as shown in FIG. 6(d), by using a resist mask not shown, the protective insulating film 50 and the poly-Si film 41c are patterned. During the patterning, a surface portion of the a-Si film 41a may also be etched. As a result, a protective insulating layer 5 is obtained from the protective insulating film 50, and an a-Si layer 4a and a poly-Si layer 4c are obtained respectively from the a-Si film 41a and the poly-Si film 41c. The subsequent steps are steps described above with reference to FIG. 3.

Forming the semiconductor layer 4 by this method provides an advantage of higher freedom in selecting the material and thickness of each layer, than by the method illustrated in FIG. 3. For example, the kind of semiconductor and its composition (e.g., the composition ratio In:Ga:Zn between metallic elements in the case of an In—Ga—Zn—O-based semiconductor) may differ between the amorphous semiconductor layer (lower layer) and the crystalline semiconductor layer (upper layer). Moreover, it is possible to set the thickness of the crystalline semiconductor layer without considering the melting depth; therefore, the crystalline semiconductor layer can be made thicker. On the other hand, the method illustrated in FIG. 3 provides advantages such as a reduced number of film formation steps, reduced interfacial strain because of a transitional region being formed in the semiconductor layer 4, etc., as compared to the method according to this Variant.

A TFT according to the present embodiment can be suitably used for an active matrix substrate of a display apparatus or the like, for example. An active matrix substrate (or a display apparatus) has a displaying region that includes a plurality of pixels and a non-displaying region (also referred to as a peripheral region) other than the displaying region. For each pixel, a pixel TFT is provided as a switching element. In the peripheral region, gate drivers or other driving circuits may be monolithically formed. The driving circuits include a plurality of TFTs (“referred to as circuit TFTs”). A TFT according to the present embodiment may be used as each pixel TFT and/or each circuit TFT.

The aforementioned active matrix substrate is suitably used for a liquid crystal display apparatus. For example, a counter substrate having a counter electrode and a color filter layer may be provided; the active matrix substrate and the counter substrate may be attached together via a sealant; and liquid crystal may be injected between these substrates, a liquid crystal display apparatus is obtained.

Without being limited to a liquid crystal display apparatus, any material of which optical property can be modulated or which can emit light upon voltage application may be used as a display medium layer, whereby various display apparatuses can be obtained. For example, the active matrix substrate according to the present embodiment can be suitably used for display apparatuses such as an organic EL display apparatus or an inorganic EL display apparatus in which an organic or inorganic phosphor material is used as a display medium layer. Furthermore, it can also be suitably used as an active matrix substrate for use in an X-ray sensor, a memory device, or the like.

### INDUSTRIAL APPLICABILITY

Embodiments of the present invention are broadly applicable to apparatuses and electronic appliances that include TFTs, for example: circuit boards of active matrix substrates or the like; display apparatuses such as liquid crystal display apparatuses, organic electroluminescence (EL) display apparatus, and inorganic electroluminescence display apparatuses; imaging devices such as radiation detectors and image sensors; electronic devices such as image input devices and fingerprint reader devices, and the like.

### REFERENCE SIGNS LIST

1: substrate, 2: gate electrode, 3: gate insulating layer, 4: semiconductor layer, 4a: a-Si layer, 4c: poly-Si layer, 4t: transitional region, 5: protective insulating layer, 5s, 5d: aperture, 6A: i type a-Si layer, 6B: n⁺ type a-Si layer, 7s, 7d: amorphous contact layer, 9s, 9d: poly-Si layer side surface subportion, 8d: drain electrode, 8a: source electrode, 11: inorganic insulating layer, 12: organic insulating layer, 13: pixel electrode, 30: laser light, 40: a-Si film for the active layer, 40a: a-Si region, 40c: poly-Si region, 50: protective insulating film, 101, 102, 103: thin film transistor, Cs: first contact layer, Cd: second contact layer, M: resist mask, Rc: active region, Rd: second semiconductor region, Rs: first semiconductor region

1. A thin film transistor comprising:
a substrate;
a gate electrode supported by the substrate;
a gate insulating layer covering the gate electrode;
a semiconductor layer being disposed on the gate insulating layer and including an amorphous semiconductor layer and a crystalline semiconductor layer that is disposed on a portion of the amorphous semiconductor layer, the semiconductor layer including an active region, a first semiconductor region and a second semiconductor region, the active region including the crystalline semiconductor layer and the portion of the amorphous semiconductor layer, the first semiconductor region and the second semiconductor region, when viewed from a normal direction of the substrate, respectively including a first amorphous portion and a second amorphous portion of the amorphous semiconductor layer that are located on opposite sides of the active region;
a protective insulating layer disposed on the crystalline semiconductor layer so as to expose a side surface of the crystalline semiconductor layer and the first semiconductor region and the second semiconductor region;
a first contact layer disposed on the semiconductor layer and the protective insulating layer, the first contact layer including a first amorphous contact layer composed of an amorphous semiconductor, the first amorphous contact layer being directly in contact with the first semiconductor region of the semiconductor layer and with a portion of the side surface of the crystalline semiconductor layer,
a second contact layer disposed on the semiconductor layer and the protective insulating layer, the second contact layer including a second amorphous contact layer composed of an amorphous semiconductor, the second amorphous contact layer being directly in contact with the second semiconductor region of the semiconductor layer and with another portion of the side surface of the crystalline semiconductor layer,
a source electrode electrically connected to the crystalline semiconductor layer via the first contact layer; and
a drain electrode electrically connected to the crystalline semiconductor layer via the second contact layer.

2. The thin film transistor of claim 1, wherein the first amorphous contact layer is directly in contact with the first amorphous portion of the amorphous semiconductor layer, and the second amorphous contact layer is directly in contact with the second amorphous portion of the amorphous semiconductor layer.

3. The thin film transistor of claim 1, wherein, when viewed from the normal direction of the substrate, peripheral edges of the protective insulating layer and the crystalline semiconductor layer are aligned with each other.

4. The thin film transistor of claim 1, wherein the first amorphous contact layer and the second amorphous contact layer are n type amorphous semiconductor layers containing an n type impurity.

5. The thin film transistor of claim 1, wherein the first amorphous contact layer and the second amorphous contact layer are i type amorphous semiconductor layers that substantially do not contain any n type impurity.

6. The thin film transistor of claim 1, wherein the crystalline semiconductor layer and the amorphous semiconductor layer are composed of a same semiconductor film.

7. The thin film transistor of claim 1, wherein the semiconductor layer includes, between the crystalline semiconductor layer and the amorphous semiconductor layer, a transitional region containing crystal particles dispersed within an amorphous semiconductor.

8. The thin film transistor of claim 1, wherein the crystalline semiconductor layer and the amorphous semiconductor layer are composed of mutually different semiconductor films.

9. The thin film transistor of claim 1, wherein the crystalline semiconductor layer is a polysilicon layer, and the amorphous semiconductor layer is an amorphous silicon layer.

10. The thin film transistor of claim 1, wherein the crystalline semiconductor layer is a crystalline oxide semiconductor layer, and the amorphous semiconductor layer is an amorphous oxide semiconductor layer.

11. A display apparatus comprising:
the thin film transistor of claim 1; and
a displaying region including a plurality of pixels, wherein
the thin film transistor is disposed correspondingly to each of the plurality of pixels.

12. A production method for a thin film transistor supported by a substrate, comprising:
(A) a step of forming, on the substrate, a gate electrode and a gate insulating layer covering the gate electrode;
(B) a step of forming an amorphous semiconductor film on the gate insulating layer;
(C) a step of irradiating at least a portion of a surficial portion of the amorphous semiconductor film with laser light to melt and solidify the portion and form a crystalline region, and to leave a portion that is located below the surficial portion as an amorphous region, the step thus forming a semiconductor film that includes the amorphous region and the crystalline region;
(D) a step of forming a protective insulating film on the semiconductor film;
(E) a step of, by using a first mask, patterning the protective insulating film and the semiconductor film to form from the protective insulating film a protective insulating layer that covers only a portion of the crystalline region and to thin-film any portion of the semiconductor film that is not covered by the protective insulating layer, the step thus forming a semiconductor layer that includes an amorphous semiconductor layer formed from the amorphous region and a crystalline semiconductor layer formed from the portion of the crystalline region, the semiconductor layer including, when viewed from a normal direction of the substrate, an active region that includes the crystalline semiconductor layer and includes a portion of the amorphous semiconductor layer that is located under the crystalline semiconductor layer, and a first semiconductor region and a second semiconductor region which respectively include portions of the amorphous semiconductor layer that are located on opposite sides of the active region;
(F) a step of forming a film for contact layer formation that covers the protective insulating layer and the semiconductor layer, the film for contact layer formation being a film of amorphous semiconductor, or a multilayer film having a film of an amorphous semiconductor as a lowermost layer;
(G) a step of forming an electrically conductive film on the film for contact layer formation; and
(H) a step of, by using the protective insulating layer as an etchstop, patterning the film for contact layer formation and the electrically conductive film to form from the electrically conductive film a source electrode and a drain electrode that are separated from each other, and to form from the film for contact layer formation a first contact layer and a second contact layer, wherein the first contact layer is located between the semiconductor layer and the source electrode and is directly in contact with a portion of a side surface of the crystalline semiconductor layer and with the first semiconductor region, and wherein the second contact layer is located between the semiconductor layer and the drain electrode and is directly in contact with another portion of the side surface of the crystalline semiconductor layer and with the second semiconductor region.

13. The production method of claim 12, wherein, in step (E), the portion of the semiconductor film that is not covered by the protective insulating layer is thin-filmed until the amorphous region is exposed.

14. The production method of claim 12, wherein the amorphous semiconductor layer is an amorphous silicon layer, and the crystalline semiconductor layer is a polysilicon layer.

15. The production method of claim 12, wherein the crystalline semiconductor layer is a crystalline oxide semiconductor layer, and the amorphous semiconductor layer is an amorphous oxide semiconductor layer.

16. The production method of claim 12, wherein the film of amorphous semiconductor of the film for contact layer formation is an n type amorphous silicon film containing an n type impurity.
